(19) United States
(12) Patent Application Publication
(10) Pub. No.: US 2013/0329429 A1
(43) Pub. Date: Dec. 12, 2013

(54) EMITTER PACKAGE WITH INTEGRATED MIXING CHAMBER

(71) Applicant: Cree, Inc., Durham, NC (US)

(72) Inventors: Theodore Lowes, Lompoc, CA (US); Deborah Kircher, Santa Barbara, CA (US)

(21) Appl. No.: 13/902,080

(22) Filed: May 24, 2013

Related U.S. Application Data
(63) Continuation-in-part of application No. 13/770,389, filed on Feb. 19, 2013.
Application No. 13/770,389 is a continuation-in-part of application No. 13/649,067, filed on Oct. 10, 2012.
Application No. 13/649,067 is a continuation-in-part of application No. 13/649,052, filed on Oct. 10, 2012.
(60) Provisional application No. 61/658,271, filed on Jun. 11, 2012.
(60) Provisional application No. 61/660,231, filed on Jun. 15, 2012.
(60) Provisional application No. 61/696,205, filed on Sep. 2, 2012.

(51) Int. Cl. F21K 99/00; H01L 33/60; H01L 33/08

(52) U.S. Cl. CPC F21K 9/54; H01L 33/08; H01L 33/60
USPC 362/247; 257/89; 257/98

(57) ABSTRACT

LED packages are disclosed having encapsulants which can have at least one reflective surface. Due to the reflection of light, the encapsulant can serve as a mixing chamber and thus can produce light of a more uniform color. The encapsulant can take many different shapes, including that of a cylinder and that of a rectangular prism. Encapsulants can also include scatterers to further mix the light.

This application is a continuation-in-part of and claims the benefit of U.S. patent application Ser. No. 13/770,389, filed on Feb. 19, 2013, which is a continuation-in-part of and claims the benefit of U.S. patent application Ser. No. 13/649,067, and U.S. patent application Ser. No. 13/649,052, both of which were filed on Oct. 10, 2012, both of which claim the benefit of U.S. Provisional Patent Application Ser. No. 61/658,271, filed on Jun. 11, 2012, U.S. Provisional Patent Application Ser. No. 61/660,231, filed on Jun. 15, 2012, and U.S. Provisional Patent Application Ser. No. 61/696,205, filed on Sep. 2, 2012. Each of the above U.S. Patents, U.S. Patent Applications, and U.S. Provisional Patent Applications is hereby incorporated by reference in its entirety.

### BACKGROUND OF THE INVENTION

1. Field of the Invention

This invention pertains to solid state light emitters and in particular to light emitting diode (LED) packages with integrated mixing chambers.

2. Description of the Related Art

Incandescent or filament-based lamps or bulbs are commonly used as light sources for both residential and commercial facilities. However, such lamps are highly inefficient light sources, with as much as 95% of the input energy lost, primarily in the form of heat or infrared energy. One common alternative to incandescent lamps, so-called compact fluorescent lamps (CFLs), are more effective at converting electricity into light but require the use of toxic materials which, along with its various compounds, can cause both chronic and acute poisoning and can lead to environmental pollution. One solution for improving the efficiency of lamps or bulbs is to use solid state devices such as light emitting diodes (LED or LEDs), rather than metal filaments, to produce light.

Light emitting diodes generally comprise one or more active layers of semiconductor material sandwiched between oppositely doped layers. When a bias is applied across the doped layers, holes and electrons are injected into the active layer where they recombine to generate light. Light is emitted from the active layer and from various surfaces of the LED.

In order to use an LED chip in a circuit or other like arrangement, it is known to enclose an LED chip in a package to provide environmental and/or mechanical protection, color selection, light focusing and the like. An LED package can also include electrical leads, contacts or traces for electrically connecting the LED package to an external circuit. In a typical LED package 10 illustrated in FIG. 1, a single LED chip 12 is mounted on a reflective cup 13 by means of a solder bond or conductive epoxy. One or more wire bonds 11 connect the ohmic contacts of the LED chip 12 to leads 15A and/or 15B, which may be attached to or integral with the reflective cup 13. The reflective cup may be filled with an encapsulant material 16 which may contain a wavelength conversion material such as a phosphor. Light emitted by the LED at a first wavelength may be absorbed by the phosphor, which may responsively emit light at a second wavelength. The entire assembly is then encapsulated in a clear protective resin 14, which may be molded in the shape of a lens to collimate the light emitted from the LED chip 12. While the reflective cup 13 may direct light in an upward direction, optical losses may occur when the light is reflected (i.e. some light may be absorbed by the reflective cup due to the less than 100% reflectivity of practical reflector surfaces). In addition, heat retention may be an issue for a package such as the package 10 shown in FIG. 1, since it may be difficult to extract heat through the leads 15A, 15B.

A conventional LED package 20 illustrated in FIG. 2 may be more suited for high power operations which may generate more heat. In the LED package 20, one or more LED chips 22 are mounted onto a carrier such as a printed circuit board (PCB) carrier, substrate or submount 23. A metal reflector 24 mounted on the submount 23 surrounds the LED chip(s) 22 and reflects light emitted by the LED chips 22 away from the package 20. The reflector 24 also provides mechanical protection to the LED chips 22. One or more wirebond connections 27 are made between ohmic contacts on the LED chips 22 and electrical traces 25A, 25B on the submount 23. The mounted LED chips 22 are then covered with an encapsulant 26, which may provide environmental and mechanical protection to the chips while also acting as a lens. The metal reflector 24 is typically attached to the carrier by means of a solder or epoxy bond.

LED chips, such as those found in the LED package 20 of FIG. 2 can be coated by conversion material comprising one or more phosphors, with the phosphors absorbing at least some of the LED light. The LED chip can emit a different wavelength of light such that it emits a combination of light from the LED and the phosphor. The LED chip(s) can be coated with a phosphor using many different methods, with one suitable method being described in U.S. patent applications Ser. Nos. 11/656,759 and 11/899,790, both to Chitnis et al. and both entitled “Wafer Level Phosphor Coating Method and Devices Fabricated Utilizing Method”. Alternatively, the LED chips can be coated using other methods such as electrophoretic deposition (EPD), with a suitable EPD method described in U.S. patent application Ser. No. 11/473,089 to Tarsa et al. entitled “Close Loop Electrophoretic Deposition of Semiconductor Devices”.

Another conventional LED package 30 shown in FIG. 3 comprises an LED 32 on a submount 34 with a hemispheric lens 36 formed over it. The LED 32 can be coated by a conversion material that can convert all or most of the light from the LED. The hemispheric lens 36 is arranged to minimize total internal reflection of light. The lens is made relatively large compared to the LED 32 so that the LED 32 approximates a point light source under the lens. As a result, the amount of LED light that emits from the surface of the lens 36 on the first pass is maximized. This can result in relatively large devices where the distance from the LED to the edge of the lens is maximized, and the edge of the submount can extend out beyond the edge of the encapsulant. These devices generally produce a Lambertian emission pattern that is not always ideal for wide emission area applications. In some conventional packages the emission profile can be approximately 120 degrees full width at half maximum (FWHM).

Lamps have also been developed utilizing solid state light sources, such as LED chips, in combination with a conversion material that is separated from or remote to the LED chips. Such arrangements are disclosed in U.S. Pat. No. 6,350,041 to Tarsa et al., entitled “High Output Radial Dispersing Lamp Using a Solid State Light Source.” The lamps described therein can comprise a solid state light source that transmits light through a separator to a disperser having a phosphor. The disperser can disperse the light in a desired pattern and/or changes its color by converting at least some of the light to a different wavelength through a phosphor or other conversion material. In some embodiments the separator spaces the light source a sufficient distance from the disperser such that heat from the light source will not transfer to the disperser when the light source is carrying elevated currents necessary for room illumination. Additional remote phosphor techniques are described in U.S. Pat. No. 7,614,759 to Negley et al., entitled “Lighting Device.”

Packages and fixtures that emit a combination of different wavelengths of light, and particularly multicolor source packages and fixtures with chips emitting different wavelengths, the sources often cast shadows with color separation and provide an output with poor color uniformity. For example, a source featuring blue and yellow sources may appear to have a blue tint when viewed head on and a yellow tint when viewed from the side. Thus, one challenge associated with multicolor light sources is good spatial color mixing over the entire range of viewing angles to achieve acceptable color spatial uniformity (“CSU”). An LED package with good CSU will emit light of relatively constant CCT across many viewing angles. One known approach to the problem of color mixing is to use a diffuser to scatter light from the various sources.

Another known method to improve color mixing is to reflect or bounce the light off of several surfaces before it is emitted from the lamp; these bounces can often take place in what is known as a mixing chamber. This has the effect of disassociating the emitted light from its initial emission angle. Uniformity typically improves with an increasing number of bounces, but each bounce has an associated optical loss. Some applications use intermediate diffusion mechanisms (e.g., formed diffusers and textured lenses) to mix the various colors of light. While the mixing chamber approach has resulted in very high efficacies for the LR6 lamp of approximately 60 lumens/watt, one drawback of this approach is that a minimum spacing is required between the diffuser lens (which can be a lens and diffuser film) and the light sources. The actual spacing can depend on the degree of diffusion of the lens but, typically, higher diffusion lenses have higher losses than lower diffusion lenses. Thus, the level of diffusion/obscuration and mixing distance are typically adjusted based on the application to provide a light fixture of appropriate depth. In different lamps, the diffuser can be 2 to 3 inches from the discrete light sources, and if the diffuser is closer the light from the light sources may not mix sufficiently. Accordingly, it can be difficult to provide very low profile light fixtures utilizing the mixing chamber approach. Another disadvantage of previous mixing chamber approaches where near field mixing is achieved is that many of the secondary and tertiary elements included to encourage mixing (e.g., diffusers) are lossy and, thus, improve the color uniformity at the expense of the optical efficiency of the device. Indirect troffers which utilize a mixing chamber to mix light are described generally in U.S. Pat. No. 7,722,220 to Van de Ven and entitled “Lighting Device,” lamps designed to achieve near field mixing are described generally in U.S. patent application Ser. No. 12/475,261 to Negley et al. and entitled “Light Source with Near Field Mixing,” both of which are commonly assigned with the present application and are fully incorporated by reference herein in their entirety.

### SUMMARY OF THE INVENTION

Briefly, and in general terms, the invention is directed toward encapsulants, emitter packages, and lighting fixtures having improved color mixing. In some embodiments, an encapsulant includes at least one reflective surface.

One embodiment of an emitter package according to the present invention comprises one or more emitters on a submount and an encapsulant over the emitters and submount. The encapsulant includes a reflective surface.

Another embodiment of an emitter package according to the present invention comprises one or more emitters on a submount and a mixing chamber over the emitters and on the submount. The mixing chamber is configured to improve the color spatial uniformity of the emitter package.

One embodiment of an emitter encapsulant according to the present invention comprises a reflective surface and a transparent primary emission surface. The encapsulant is configured to improve the color spatial uniformity of light emission.

One embodiment of a lighting fixture according to the present invention comprises at least one emitter package on a housing. The emitter package comprises an encapsulant having at least one reflective surface.

### BRIEF DESCRIPTION OF THE DRAWINGS

FIG. 1 shows a sectional view of one embodiment of a prior art LED package;

FIG. 2 shows a sectional view of another embodiment of a prior art LED package;

FIG. 3 shows a sectional view of still another embodiment of a prior art LED package;

FIGS. 4A-4C show perspective, side, and top views of an embodiment of an LED package according to the present invention;

FIG. 5 shows the embodiment of FIGS. 4A-4C with exemplary ray traces.

FIGS. 6A-6C show perspective, side, and top views of another embodiment of an LED package according to the present invention;

FIGS. 7A-7C show perspective, side, and top views of another embodiment of an LED package according to the present invention;

FIGS. 8A-8C show perspective, side, and top views of an embodiment of an LED package comprising a scatterer according to the present invention;

FIGS. 9A-9C show perspective, side, and top views of an embodiment of an LED package with an encapsulant having angled sidewalls according to the present invention;

FIGS. 10A-10C show perspective, side, and top views of an embodiment of an LED package with an encapsulant having curved sidewalls according to the present invention;

FIGS. 11A-11C show perspective, side, and top views of another embodiment of an LED package with an encapsulant having curved sidewalls according to the present invention;

FIGS. 12A-12C show perspective, side, and top views of an embodiment of an LED package with a multi-section encapsulant according to the present invention;

FIGS. 13A-13C show perspective, side, and top views of an embodiment of an LED package with an encapsulant having shaped sidewalls according to the present invention;

FIGS. 14A-14C show perspective, side, and top views of an embodiment of an LED package with a shaped emission surface according to the present invention;

FIGS. 15A-15C show perspective, side, and top views of another embodiment of an LED package with a shaped emission surface according to the present invention;

FIGS. 16A-16C show perspective, side, and top views of another embodiment of an LED package with a shaped emission surface according to the present invention;

FIGS. 17A-17C show perspective, side, and top views of another embodiment of an LED package with a shaped emission surface according to the present invention;

FIGS. 18A-18C show perspective, side, and top views of another embodiment of an LED package according to the present invention; and

FIGS. 19A-19C show perspective, side, and top views of another embodiment of an LED package according to the present invention.

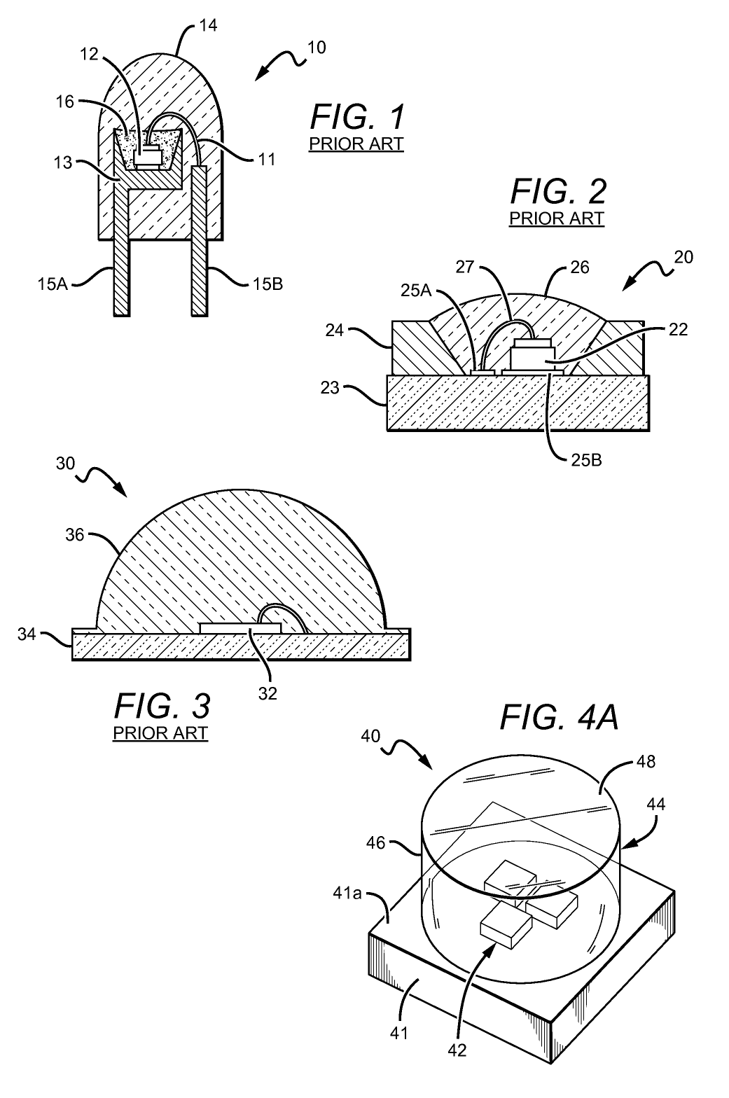

### DETAILED DESCRIPTION OF THE INVENTION

The present invention is directed to different embodiments of LED package structures with one or more light sources. Embodiments of the present invention can provide color mixing at the package level such that secondary and/or tertiary components typically needed for color mixing can be eliminated from a lighting system, improving, among other things, output efficiency and cost efficiency.

The LED packages according to the present invention can comprise a plurality of LEDs or LED chips on a submount, with contacts, attach pads and/or traces for applying an electrical signal to the one or more LED chips. The LED packages can be arranged with LED chips in many different patterns. The LED chips can have many different shapes, sizes, and features, and can include textured LED chips. The LED chips can emit different colors of light such that the LED package emits the desired color combination of light from the LED chips, and/or each LED chip can emit multiple colors of light for a desired LED chip emission (e.g., BSY LEDs for white light). Some examples of LED chip combinations that produce white light include white emitters, three chips emitting red, green, and blue light respectively (RGB), and/or four chips emitting red, green, blue, and amber light respectively (RGBA). These are only a few of chip combinations that produce white light, as many different combinations are possible. Further, various chip combinations can be used to produce any desired color of light.

The different packages according to the present invention can have an encapsulant with many different shapes, sizes, and features over one or more LED chips. In one embodiment, the encapsulant can include reflective side walls and a transparent top primary emission surface. By including reflective side walls, at least some light rays can bounce off of the side walls and back into the encapsulant instead of exiting the package through the side walls. This will cause the encapsulant to serve as a light mixing chamber, and results in a more uniform package emission when light eventually exits the package through the top primary emission surface.

The encapsulant can take many shapes, including but not limited to a cylindrical shape and a box shape. The side wall or side walls (used interchangeably herein unless otherwise noted) can be vertical (i.e. perpendicular to the submount), or can be wider than vertical. In other embodiments, the side wall or side walls can be slightly angled inward in one or more sections, or can be substantially angled inward in one or more sections. In some embodiments, the side walls form planar surfaces. Some embodiments can have LED chips and an encapsulant that can be shaped so that they have surfaces that are oblique to one another. In still other embodiments, the LED chips can be made of materials and shaped such that LED chip surfaces are generally parallel to the surfaces of the encapsulant. In some embodiments, such as embodiments with only partially reflective side walls or non-reflective side walls, a greater percentage of light will experience total internal reflection (TIR) in comparison to conventional LED packages with hemispheric type encapsulants. This can aid in color mixing within the package such that the package will emit with a more uniform color. Different package embodiments can emit different colors of light, such as white light with temperatures of approximately 2700 kelvin (k), 3000K, 3500K, 4000K and 4200K. In different embodiments, the color variation over viewing angles of +/− 90 degrees is 500K or less, while in other embodiments it can be the color variation can be 1000K or less. In still other embodiments, the variation can be 1500K or less.

Embodiments according to the present invention can have relatively smooth planar surfaces to enhance TIR. Embodiments according to the present invention can include undulated side walls, which can increase color mixing. In some embodiments where there is some texturing, roughness, and/or imperfections on the surfaces of the encapsulant, either intentionally included or the result of manufacturing processes.

The primary emission surface in some embodiments is flat, while in other embodiments it is shaped, such as, for example, a hemispherical or frustospherical surface. Other possible emission surface shapes include surfaces with divots, for example conical or frustoconical divots, emission surfaces with fillets or rounded edges, and/or textured emission surfaces. The primary emission surface can be arranged with minimal reflectivety to allow for light to readily emit from the surface.

Packages according to the present invention can also include one or more scatterers. Examples of possible scatterers include volume scatterers, such as scattering particles uniformly dispersed throughout the encapsulant. Another example of a scatterer includes a two dimensional (i.e., relatively flat and thin) layer of scattering particles which can be placed in various positions in the encapsulant, including on the top primary emission surface or just above the top of the LED chips. In other embodiments, the scatterer can be included in a layer or region that occupies less than all of the encapsulant. In other embodiments, encapsulants include different types and/or concentrations of scatterers.

The present invention is described herein with reference to certain embodiments, but it is understood that the invention can be embodied in many different forms and should not be construed as limited to the embodiments set forth herein. In particular, the present invention is described below in regards to certain LED packages having LED chips in different configurations, but it is understood that the present invention can be used for many other LED packages with other LED configurations. The LED packages can also have many different shapes beyond those described below, such as rectangular, and solder pads and attach pads can be arranged in many different ways. In other embodiments, the emission intensity of the different types of LED chips can be controlled to vary the overall LED package emission.

The present invention can be described herein with reference to conversion materials, wavelength conversion materials, remote phosphors, phosphors, phosphor layers and related terms. The use of these terms should not be construed as limiting. It is understood that the use of the term remote phosphors, phosphor or phosphor layers is meant to encompass and be equally applicable to all wavelength conversion materials.

The present invention can be described herein with reference to scatterers, scatters, scattering particles, diffusers, and related terms. The present invention can also be described herein with reference to reflectors, reflective particles, reflective surfaces, and related terms. The use of these terms should not be construed as limiting. It is understood that the use of these terms is meant to encompass and be equally applicable to all light scattering materials and/or reflective materials.

The embodiments below are described with reference to an LED or LEDs, but it is understood that this is meant to encompass LED chips, and these terms can be used interchangeably. These components can have different shapes and sizes beyond those shown, and one or different numbers of LEDs can be included. It is also understood that the embodiments described below utilize co-planar light sources, but it is understood that non co-planar light sources can also be used. It is also understood that an LED light source may be comprised of multiple LEDs that may have different emission wavelengths. As mentioned above, in some embodiments at least some of the LEDs can comprise blue emitting LEDs covered with a yellow phosphor along with red emitting LEDs, resulting in a white light emission from the LED package. In multiple LED packages, the LEDs can be serially interconnected or can be interconnected in different serial and parallel combinations.

It is also understood that when a feature or element such as a layer, region, encapsulant or submount may be referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one layer or another region. It is understood that these terms are intended to encompass different orientations of the device in addition to the orientation depicted in the figures. Further, many of the embodiments of the present invention are shown with a “top” primary emission surface. It is understood that any one or more surfaces, including but not limited to a top surface, can be (or can combine to form) a primary emission surface. For example, a package can be designed to have a primary emission out a side emission surface.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

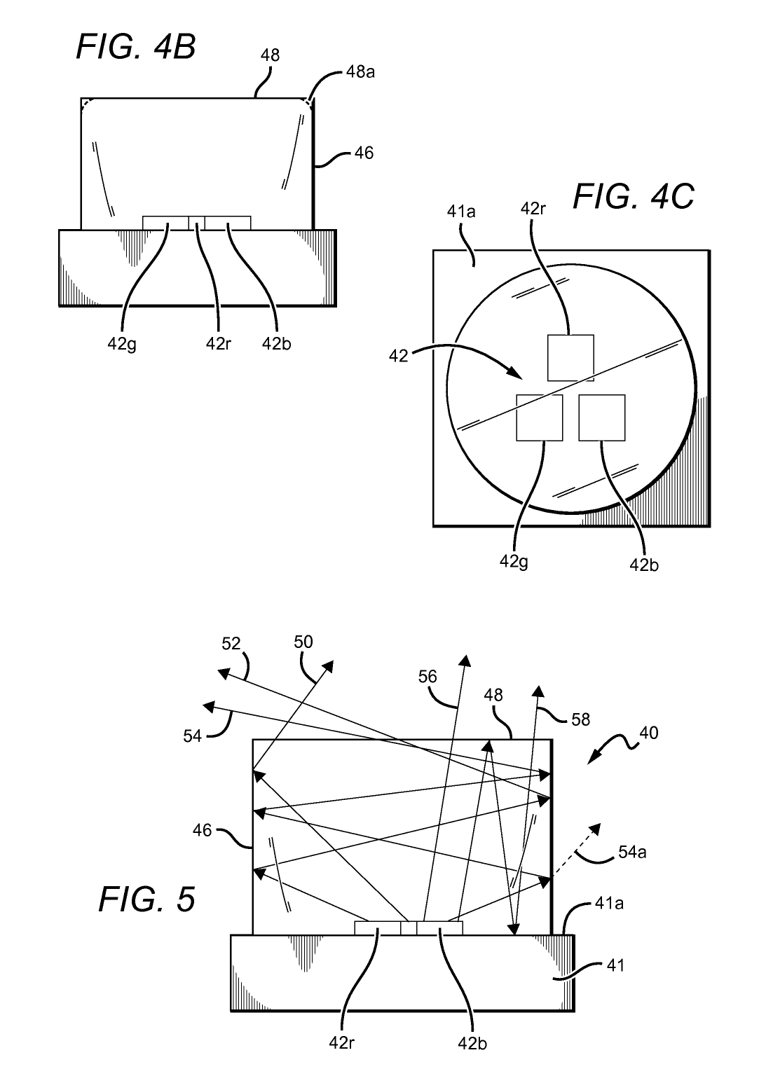

FIGS. 4A-4C show an LED package 40 according to one embodiment of the present invention. The package 40 comprises three LED chips 42r, 42g, 42b mounted on a submount 41 with a top surface 41a. An encapsulant 44 with a primary emission surface 48 is mounted over the LED chips 42.

While the package 40 can include three LED chips 42, it is understood that in other embodiments the light source can comprise one LED, two LEDs, and three or more LED chips. Many different LED chips can be used such as those commercially available from Cree, Inc. under its DA, EZ, GaN, MB, RT, TR, UT, and XT families of LED chips, among others. The package 40 includes a red LED chip 42r, a green LED chip 42g, and a blue LED chip 42b. The three LED chips can combine to form a white package emission. The LED chips 42 can be flip chip mounted and can allow for wire-free bonding, as is generally described in commonly assigned U.S. patent application Ser. No. 12/463,709 to Donofrio et al. and entitled “Semiconductor Light Emitting Diodes Having Reflective Structures and Methods of Fabricating Same,” which is fully incorporated by reference herein in its entirety. It is understood that in some embodiments one or more of the LED chips 42 can be provided following removal of its growth substrate. In other embodiments, the growth substrate can remain on the LED chip 42, with some of these embodiments having a shaped or textured growth substrate. In some embodiments, the LED chips 42 can comprise a transparent growth substrate such as silicon carbide, sapphire, GaN, GaP, etc. The LED chips 42 can also comprise a three dimensional structure and in some embodiments can have a structure comprising entirely or partially oblique facets on one or more surfaces of the chip 42.

The package 40 can also comprise submount 41, with the LED chips 42 mounted on the submount 41. The submount 41 can be formed of many different materials. The submount can be electrically insulating, such as a submount comprising a dielectric material. The submount 41 can comprise a ceramic such as alumina, aluminum nitride, silicon carbide, or a polymeric material such as polymide and polyester. The submount 41 can comprise a dielectric material having a relatively high thermal conductivity, such as aluminum nitride and alumina. In other embodiments the submount 41 can comprise a printed circuit board (PCB), sapphire or silicon or any other suitable material, such as T-Clad thermal clad insulated substrate material, available from The Bergquist Company of Chanhassen, Minn. For PCB embodiments different PCB types can be used such as standard FR-4 PCB, metal core PCB, or any other type of printed circuit board.

The LED chips 42 can be mounted to the submount 41 in many different ways including using die attach pads which can provide an electrical connection to the LED chips 42. Such packages are described generally in commonly assigned U.S. patent application Ser. No. 13/770,389 to Lowes et al. and entitled “LED Package With Multiple Element Light Source and Encapsulant Having Planar Surfaces,” which is fully incorporated by reference herein and from which this application claims priority. The LED chips 42 can also be electrically connected using known surface mount or wire bonding methods.

The encapsulant 44 can be included over the LED chips 42 and submount 41 and can provide environmental and mechanical protection, and can allow for recycling of light which will be described in more detail below. Unlike most conventional encapsulants, the encapsulant 44 can have a vertical side wall 46 and can be generally cylindrical or rod shaped (and thus can have a generally square or rectangular vertical cross-section and a circular horizontal cross-section). While the vertical side wall 46 can be vertical, other side walls according to the present invention are angled slightly inward at 85° from the substrate, are between 85° and vertical, or are angled wider than vertical. The encapsulant 44 has a height-to-width (h:w) ratio of approximately 1:1, although smaller and larger h:w ratios are possible and will be discussed below. The encapsulant 44 also has a flat top surface 48, which in this case serves as the primary emission surface. In some embodiments according to the present invention, encapsulant surfaces can have rounded edges or fillets 48a as shown by the dashed lines in FIG. 4B, which can decrease total internal reflection. Many different shapes of encapsulants are possible, including but not limited to encapsulants with angled side walls, shaped top surfaces, and encapsulants with different prismatic or polygon shapes such as triangles, pentagons, hexagons, octagons, star shapes, starburst shapes, etc. Some embodiments can include more than one top surface, and any number of vertical surfaces ranging from 1 to 16 or more. Other embodiments of encapsulants may have an oval horizontal cross-section. Some encapsulant shapes that can be used in embodiments of packages according to the present invention are described in commonly assigned U.S. patent application Ser. No. 13/804,309 to Castillo et al. and entitled “LED Dome with Improved Color Spatial Uniformity,” which shows encapsulants having two or more sections and is fully incorporated by reference herein in its entirety.

The encapsulant 44 and submount 41 can have essentially the same footprint, but it is understood that in other embodiments the footprint of one can be larger than the other. In some embodiments, the encapsulant can also have portions along its height that are larger than the submount, and can extend beyond the footprint of the submount in different portion along the encapsulant height. In some of these embodiments, the top portion or surface can have a footprint with a dimensions equal to the submount, but not greater.

In some embodiments of the invention, encapsulant emission surfaces such as the flat top surface 48 can be textured using an optical texturing process such as mechanical or chemical etching, and/or can contain micro-optics such as microlenses. Texturing of an emission surface can help to randomize the emission angle of light rays, thus further improving the color uniformity of the package emission. A textured emission surface can also decrease total internal reflection from the emission surface, which can increase package efficiency by, for example, reducing the number of bounces off the primary emission surface a ray of light experiences and reducing the amount of light absorbed by the submount 41. Textured encapsulant surfaces and methods for forming them are described generally in commonly assigned U.S. patent application Ser. No. 12/002,429 to Loh et al. and entitled “Textured Encapsulant Surface in LED packages,” and optical texturing and micro-optics such as microlenses are described in the commonly assigned U.S. patent application Ser. No. 13/442,311 filed on Apr. 9, 2012, both of which are fully incorporated by reference herein in their entirety.

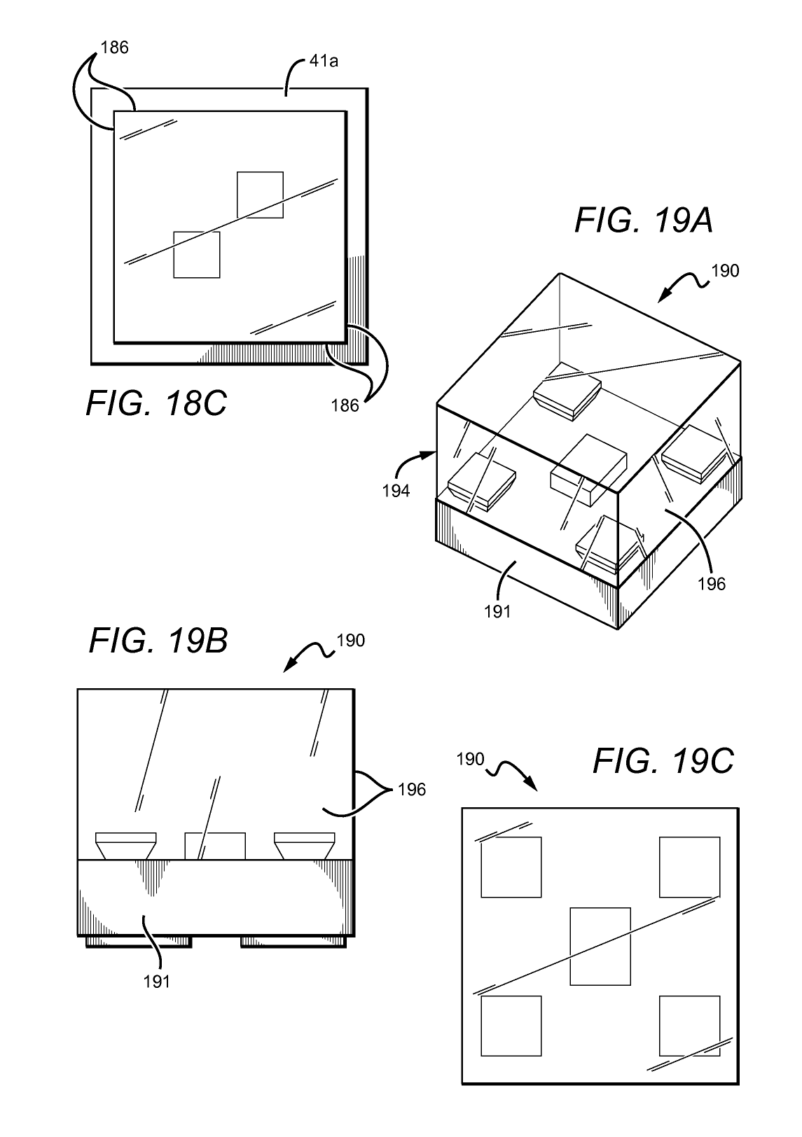

Also unlike many conventional encapsulants, the encapsulant 44 can include an at least partially reflective side wall 46 which can aid in color mixing. In some embodiments, the side wall 46 is fully reflective. While the below discussion will refer to a single side wall 46, this is only because the encapsulant 44 has a circular cross-section; the discussion is also applicable to encapsulants with two or more side walls (as shown below with regard to FIGS. 18 and 19). Many different materials can be used to achieve the desired reflectivity of the side wall 46. Some suitable materials include white paper or white film, such as White97™ Film available from WhiteOptics, LLC, of New Castle, Del. Other suitable materials include reflective metals or plastics, particularly white plastics such as one or more layers of microcellular polyethylene terephthalate (MCPET). Yet more suitable materials include reflective coatings and/or paints or coatings and/or paints including reflective particles, such as those described in U.S. Pat. No. 8,361,611 to Teather et al. and entitled “Diffusively Light Reflective Paint Composition, Method for Making Paint Composition, and Diffusively Light Reflective Particles,” which is fully incorporated by reference herein in its entirety. Many other reflective materials can be used in embodiments of packages according to the present invention. Further, the side wall 46 can have one or more different types of reflectivity, including diffuse reflectivity, specular reflectivity, and/or combinations thereof. The reflective side wall 46 can also be textured. Textured reflectors are described in commonly assigned U.S. patent application Ser. No. 13/345,215 to Lu et al. and entitled “Light Fixture with Textured Reflector,” which is fully incorporated by reference herein in its entirety.

In one embodiment of an encapsulant 44, the side wall 46 is made as reflective as possible up to 100% reflectivity, with the light experiencing TIR being approximately 100% reflected. Some embodiments of side walls can be approximately 90% or more reflective; some embodiments can be approximately 95% or more reflective; some embodiments can be approximately 97% or more reflective; and still some other embodiments can be approximately 98% or more reflective. However, in other embodiments of encapsulants, less reflectivity may be desired, and the side wall 46 can be designed to be partially transparent or translucent. In one such embodiment, a combination of the partially reflective side wall 46 and the increased TIR caused by the angles of the side wall 46 (which will be discussed in detail below) can achieve the desired reflectivity and light mixing. Further, different surfaces can have different reflectivities. For example, in a cubic encapsulant, three side surfaces can be reflective while another surface is transparent or partially transparent. Such a transparent surface can still reflect light back into the encapsulant through TIR.

In one embodiment of an encapsulant 44, the reflective side wall 46 is uniformly reflective. However in other embodiments, different sections of the encapsulant side wall 46 can have different reflectivity. For example, in one embodiment an upper portion of the side wall 46 is less reflective than a lower portion of the side wall 46. Some of these embodiments can have a wider emission profile, since some light will exit the upper portion of the side wall 46 instead of the top surface 48. In one such embodiment, at least some of the light exiting the upper less reflective portion of the side wall 46 has already been sufficiently mixed due to bouncing off of the lower more reflective portion of the side wall 46. Other embodiments with variable reflectivity are also possible.

The reflective coating of encapsulants according to the present invention can also be applied in any number of ways. For example, the reflective material, such as reflective white paper, can be included on the sides of a mold corresponding to the sides of the encapsulant where the coating is to be deposited. As another example, the sides of the encapsulant could be coated with a reflective material after the encapsulant has been cured. As yet another example, the encapsulant could be immersed or dipped in a reflective material. As yet another example, the a reflective material such as reflective white paper could be applied after the encapsulant is cured. As yet another example, the reflective material could be sputtered or painted onto the encapsulant.

FIG. 5 shows a cross-sectional view of the LED package 40 from FIGS. 4A-4C with several ray traces. The ray traces 50, 52, 54 represent beams of light that bounce off of the reflective side wall 46 one, two, and three times, respectively. Generally speaking, the more times rays of light are bounced, the more uniform the output color of the package 40 will be, due in part to the fact that the light ray will be disassociated from its initial position and initial output angle. For example, in the cross-sectional view shown, the light ray 52 is emitted from the red-emitting chip 42r, which is on the left side of the package 40, while the light ray 54 is emitted from the blue-emitting chip 42b on the right side of the package 40. In the specific case of the light rays 52,54 because the light rays 52,54 have become disassociated from their point of origin on the chips 42r, 42b, they emit at approximately the same angle, which can result in a more uniformly mixed package output. A package can have a relatively uniform emission if a substantial amount of light rays bounce two or more times. In the case of a package with a completely reflective side wall 46, the emission of the package 40 can be generally Lambertian from the flat emission surface 48. While the bounces off of the reflective side wall 46 can cause optical losses, these losses can be less than the losses that would be associated with secondary and/or tertiary mixing elements while achieving equal or better color mixing.

In addition to the reflective side wall 46, the package 40 also comprises a substrate 41 with a top surface 41a that can be reflective. Some light, such as a light ray 58, emitted from the chips 42 can be reflected back towards the chips 42 and substrate 41 by the emission surface 48 due to total internal reflection (TIR). The reflective top substrate surface aids package emission by redirecting the light ray 58 toward the emission surface 48 instead of simply absorbing the light, resulting in a more efficient package emission.

If a side wall is only partially reflective, then some light can pass through the side wall. Such a light ray 54a can be slightly refracted due to the difference in the refractive indexes of the materials through which the light travels. By allowing some light to pass through a partially reflective side wall, the emission pattern of the package as a whole can be broadened. Further, partially reflective side walls can be used to tailor the overall emission pattern.

The shape of the encapsulant 44 can also be designed to encourage color mixing by capitalizing on the total internal reflection (TIR) of light within the package 40, such as if the side wall 46 is not completely reflective. The encapsulant 44 is shaped such that a substantial amount of light can be incident on the side wall 46 is incident on the side wall 46 at an angle that causes TIR, and thus is reflected back into the encapsulant 44. Light reflected due to TIR and light reflected back into the encapsulant 44 due to a reflective material are recycled into the encapsulant, and thus photon recycling occurs. This recycled light will then be disassociated from its original emission position and angle, and then reach the emission surface 46 of the encapsulant at an angle less than the critical angle and emit from the package. Side walls angled at approximately 85° or greater from the substrate are known to promote TIR and photon recycling.

In a typical LED package, the light source must be relatively small compared to the encapsulant so as to approximate a point source. By arranging the LED package 40 to provide photon recycling of reflected light (such as both light reflected due to the reflectivity of the side wall 46 and due to TIR), the LED package 40 can have relatively larger light sources. For example, the light source can have sides that are approximately 90% the length of an encapsulant side or more (for multi-chip embodiments, this width can refer to the distance from the outside edge of one emitter to the opposite outside edge of the furthest other emitter). In another embodiment, a light source side is approximately 75% that of an encapsulant side. In another embodiment, a light source side is approximately 50% that of an encapsulant side. In another embodiment, the light source side is approximately 25% that of an encapsulant side.

In still other embodiments, the light source size or width (for either single or multiple chip embodiments) can be approximately the same as the width of the encapsulant in an approximate 1:1 ratio. For some packages, manufacturing techniques can call for offsets between the edge of the encapsulant and the edge of the light source so that the encapsulant has a greater width than the light source. Some of these manufacturing processes call for offsets of at least 0.2 to 0.5 millimeters. Other embodiments can have even larger diameter encapsulants compared to the light source resulting in higher source to encapsulant ratios, such as 1:2, 1:3, 1:5 or higher.

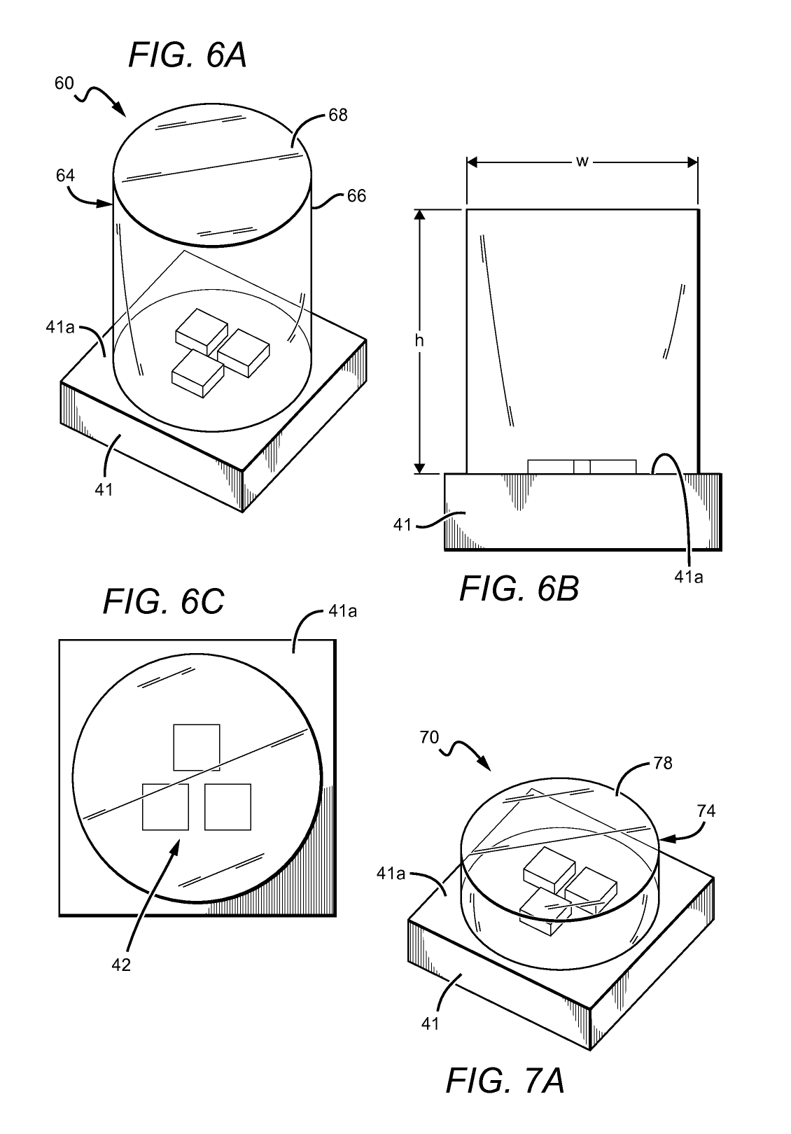

Because the overall package size can be small compared to the light source(s), the package can be smaller than other prior art packages having the same source size. For example, packages according to the present invention can be approximately 1.0 mm×1.0 mm×1.0 mm or smaller, approximately 1.3 mm×1.3 mm×1.3 mm, or approximately 1.6 mm×1.6 mm×1.6 mm or larger. Further, the package footprint in some embodiments is not square, and as described below with regard to FIGS. 6A-8C, the height of the package can vary and be less than or greater than the package width or length. Photon recycling and packages with large source sizes relative to encapsulant size are described in detail in U.S. patent application Ser. No. 13/770,389, from which this application claims priority.

FIGS. 6A-6C shows another embodiment of a package 60 according to the present invention. The package 60 is similar to the package 40, and like reference numerals are used to indicate like components. The package 60 includes an encapsulant 64 with a taller side wall 66 which can have a h:w ratio of 2. Light rays can average more bounces off of a side wall if the side wall is taller, meaning that more color mixing will occur. While the package 60 has a side wall 66 with a h:w ratio of 2, higher or lower ratios are possible. For example, an encapsulant can have an h:w ratio of 3, 4, 5, 10 or larger, and ¾, ½ or smaller.

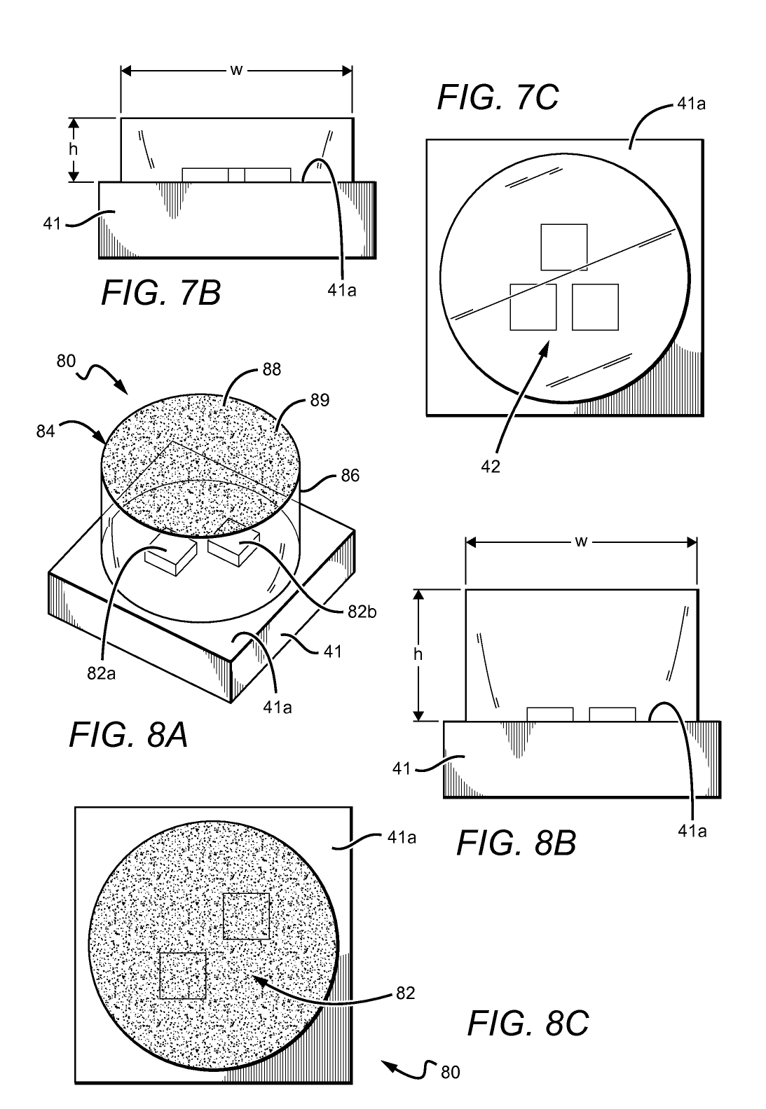

FIGS. 7A-7C shows another embodiment of a package 70 according to the present invention. The package 70 is similar in many respects to the package 40 of FIGS. 4A-4C, but has an encapsulant with an h:w ratio of less than 1, in this case 0.5. Packages according to the present invention can comprise encapsulants with many different h:w ratios under 1, such as 0.75, 0.5, 0.25, and even 0.1 or lower. Packages comprising encapsulants with lower h:w ratios are often cheaper to produce, and can be used where less color mixing is necessary.

FIGS. 8A-8C shows another embodiment of a package 80 according to the present invention similar in many respects to the package 70 of FIGS. 7A-7C. In some embodiments of the present invention such as the FIGS. 8A-8C embodiment, all or some of the LED chips 82 can be covered by a conversion material, with others of the LED chips uncovered. By using one or more LED chips 82a emitting one or more additional colors and/or having some covered by a wavelength conversion material, the color rendering index (CRI) of the lighting unit can be increased and light of a desired color temperature, such as, for example, a warm white light, can be emitted. If present, the conversion material can comprise one or more conversion materials, such as phosphors, to provide the desired LED package emission, such as white light with the desired temperature and CRI. A further detailed example of using LED chips emitting light of different wavelengths to produce substantially white light can be found in commonly assigned U.S. Pat. No. 7,213,940 to Van de Ven et al., which is fully incorporated herein by reference in its entirety.

The package 80 comprises a first LED chip 82a coated by the conversion material. The packages also include one or more of a second type of LED chip 82b emitting at a different wavelength of light, with the second LED chip 82b not covered by the conversion material. The first LED chip 82a, if illuminated, can emit a blue light having a dominant wavelength in the range of from 430 nm to 480 nm. The conversion material layer can be excited by the blue light, and can absorb at least some of the blue light and can reemit light having a dominant wavelength in the range of from about 555 nm to about 585 nm. This light can be referred to as blue shifted yellow (BSY) light. The second LED chip 82b can be uncovered by the conversion material layer and if energized with current, can emit red or orange light having a dominant wavelength in the range of from 600 nm to 650 nm.

It is understood that the LED chips can comprise LED ships emitting in different wavelength spectrums, such as the ultra violet (UV) emission spectrum. These chips can also be covered by a conversion material that is excited by UV light to emit different colors of light, and packages can include different LED chips emitting different colors of light (such as red) to achieve the desired overall package emission. The different LED chips (or phosphors) can emit light in many different wavelength ranges, such as 600-720 nm for red light, 520-565 nm for green light and 430-500 nm for blue light. These different wavelength ranges can be mixed in the packages according to the present invention, in different ways to achieve the desired white package emission.

With both the first and second LED chips 82 emitting light, the package 80 can emit a combination of (1) blue light from the LED chip 82a, (2) BSY light from the LED chip 82a absorbed by the conversion material and then reemitted, and (3) light from the LED chip 82b in the red or orange wavelength regime. In an absence of any additional light, this can produce a LED package emission mixture of light having x, y coordinates on a 1931 CIE Chromaticity Diagram different from the primary emitter wavelengths and within the polygon created by the x, y color coordinates of the emissions of the first, second LED chips 82 and the individual conversion material constituents. The combined light emission coordinates may define a point that is within a standard deviation of ten MacAdam ellipses, five MacAdam ellipses, three MacAdam ellipses, or one MacAdam ellipse of at least one point on the blackbody locus on a 1931 CIE Chromaticity Diagram. In some embodiments, this combination of light also produces a sub-mixture of light having x, y color coordinates which define a point which is within an area on a 1931 CIE Chromaticity Diagram enclosed by first, second, third, fourth and fifth connected line segments defined by first, second, third, fourth and fifth points. The first point can have x, y coordinates of 0.32, 0.40, the second point can have x, y coordinates of 0.36, 0.48, the third point can have x, y coordinates of 0.43, 0.45, the fourth point can have x, y coordinates of 0.42, 0.42, and the fifth point can have x, y coordinates of 0.36, 0.38. Another example of a package with a white light emission including both coated and uncoated LED chips is an RGBW package including a first group of BSY LED chip(s), and three groups of uncovered chip(s) emitting red, green, and blue light, respectively.

Embodiments of the present invention, including but not limited to any of the embodiments shown above or below, can also comprise scattering particles. The package 80 can also comprise scattering particles 89. The scattering particles 89 can be located in a two-dimensional layer on or at the primary emission surface 88 of the encapsulant 84. As previously discussed, the more bounces a ray of light experiences, the more disassociated with its initial emission position and angle it can become, which can lead to a more uniform and mixed package emission. The scattering particles 89 provide an opportunity for rays of light to experience one or more additional bounces. Further, scattering particles can scatter rays of light in random directions, which will further mix the package emission. By including a scatterer, the height of the reflective sidewall 86 can be reduced without sacrificing color uniformity. While some light can be absorbed by the scattering particles and therefore some optical loss can occur, in some embodiments this loss can be less than the loss that would occur from bouncing off of a side wall and/or a secondary and/or tertiary element while achieving the same or better color mixing.

Different embodiments of packages according to the invention can comprise different types and arrangements of scattering particles or scatterers. Some exemplary scattering particles include:
silica gel;
zinc oxide (ZnO);
yttrium oxide (Y₂O₃) ;
titanium dioxide (TiO₂);
barium sulfate (BaSO₄);
alumina (Al₂O₃);
fused silica (SiO₂);
fumed silica (SiO₂) ;
aluminum nitride;
glass beads;
zirconium dioxide (ZrO₂);
silicon carbide (SiC);
tantalum oxide (TaO₅);
silicon nitride (Si₃N₄) ;
niobium oxide (Nb₂O₅) ;
boron nitride (BN); and
phosphor particles (e.g., YAG:Ce, BOSE)

Other materials not listed may also be used. Various combinations of materials or combinations of different forms of the same material can also be used to achieve a particular scattering effect. For example, in one embodiment a first plurality of scattering particles includes alumina and a second plurality of scatting particles includes titanium dioxide. In other embodiments, more than two types of scattering particles are used. Scattering particles are discussed generally in the commonly assigned applications U.S. patent application Ser. No. 11/818,818 to Chakraborty et al. and entitled “Encapsulant with Scatterer to Tailor Spatial Emission Pattern and Color Uniformity in Light Emitting Diodes,” and U.S. patent application Ser. No. 11/895,573 to Chakraborty and entitled “Light Emitting Device Packages Using Light Scattering Particles of Different Size,” both of which are fully incorporated herein by reference in their entirety.

Additionally, the scattering particles 89 can be dispersed in or on the encapsulant 84 in many different ways. In the embodiment of FIGS. 8A-8C, the scattering particles 89 are arranged in a two-dimensional layer on top of the encapsulant 84 on the primary emission surface 88. In other embodiments, this two-dimensional layer of scattering particles 89 is not on top of the encapsulant 84, but at a different height within the encapsulant 84. For example, a two-dimensional layer of scattering particles 89 could be positioned very near the top of the chips 82, such that most of the light emitted by the chips would encounter this layer before encountering the encapsulant side walls 86.

The scattering particles 89 can also be arranged in three-dimensional regions of the encapsulant 84. In one embodiment, the scattering particles 89 are uniformly dispersed in the encapsulant. In another the encapsulant 84 has a lower concentration of scattering particles 89 as the distance from the chips 82 increases (e.g., the concentration can be on a high-to-low gradient from the bottom of the encapsulant to the top). In other embodiments, only a portion of the encapsulant 84, such as the bottom half, contains scattering particles. Encapsulants having different scattering particle regions are described in U.S. patent application Ser. No. 12/498,253 to Le Toquin and entitled “LED Packages with Scattering Particle Regions,” which is commonly assigned with the present application and fully incorporated by reference herein in its entirety.

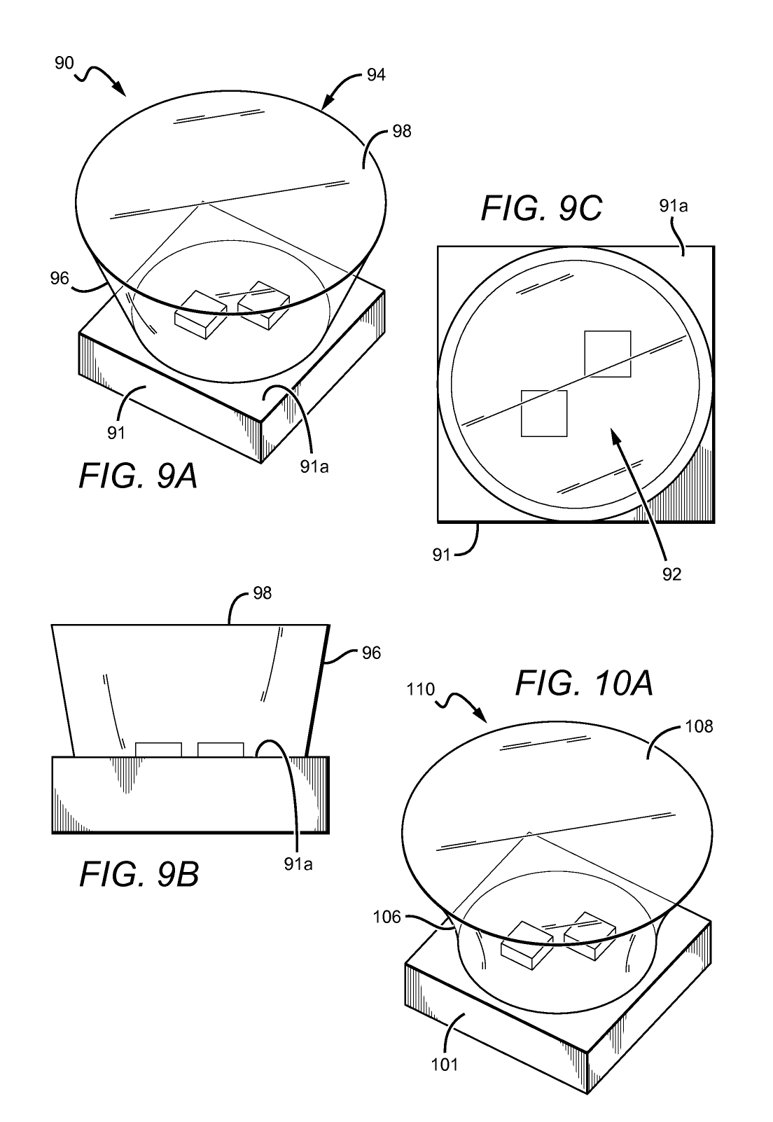

While the encapsulants shown above have included a vertical sidewall, some embodiments of the present invention include angled reflective sidewalls. The package of FIGS. 9A-9C is similar in many respects to the package 40 of FIGS. 4A-4C, but includes an encapsulant 94 with a sidewall 96 that is angled outward. It can be detrimental to package efficiency when rays of light bounce toward the substrate 91, as this light can then be partially or totally absorbed and thus contribute less to package emission. The sidewall 96 is angled such that light incident upon the sidewall is more likely to emit up and toward the primary emission surface 98 as opposed to down and toward the substrate 91. While the package 90 may have a slightly less color-uniform emission due to some rays experiencing fewer bounces within the encapsulant 94, the package 90 can have a better efficiency than a package with a cylindrical encapsulant such as the encapsulant 44 of FIGS. 4A-4C since less light will be redirected toward the substrate.

The encapsulant 94 has a top surface 98 which is larger or slightly larger than the footprint of the encapsulant 94 on the substrate 91. In some embodiments, the top surface of an encapsulant according to the present invention is as wide as or slightly less wide than the substrate. In packages that are formed on the wafer level, forming the packages with these or similar dimensions will aid with singulation.

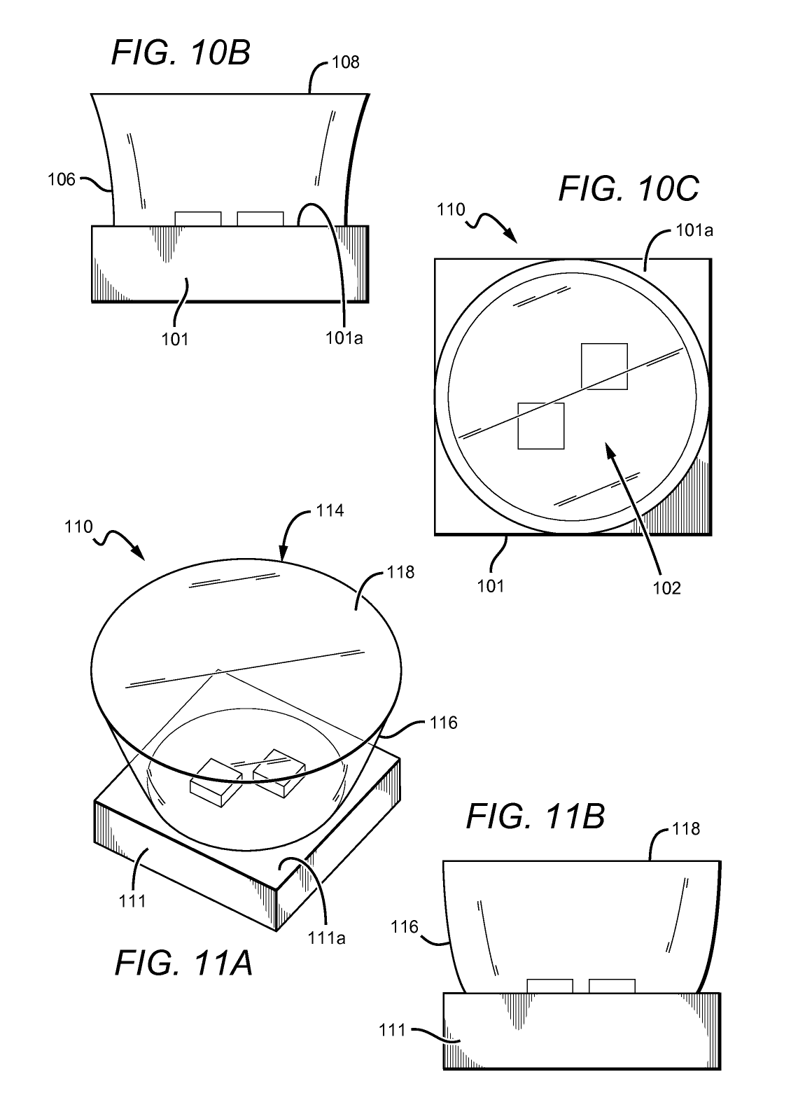

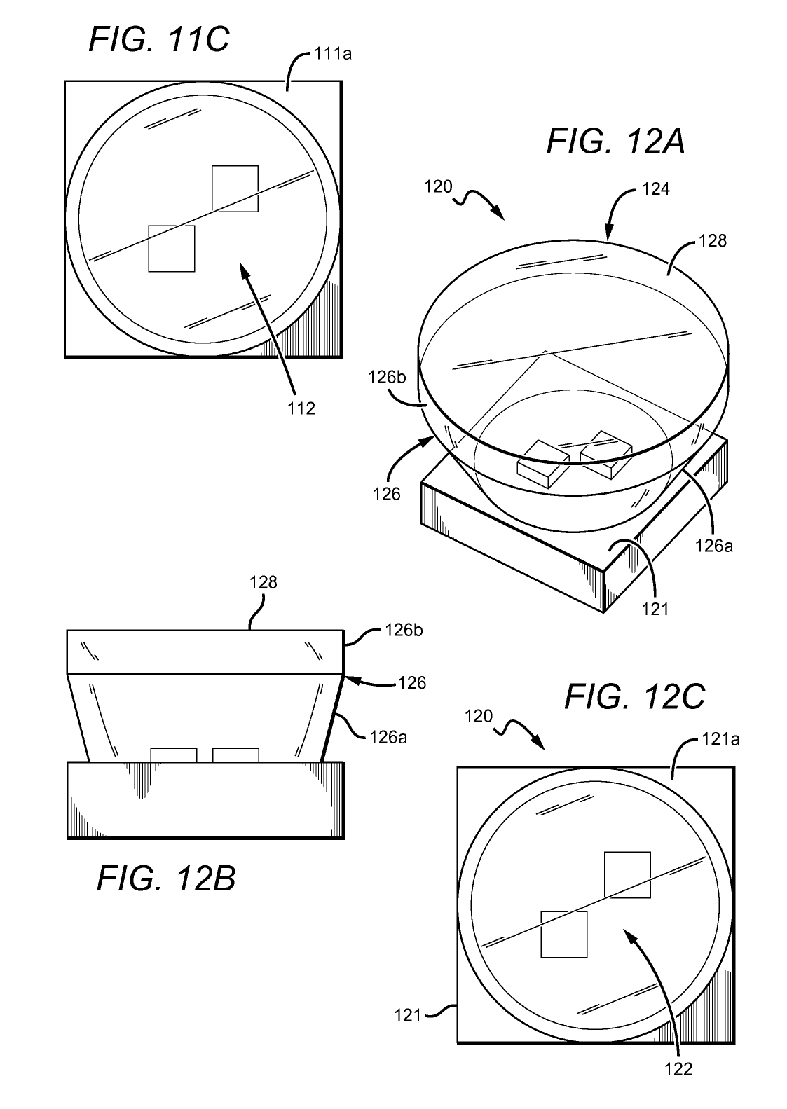

Some embodiments of packages according to the present invention can also have encapsulants with curved sidewalls. For example, the package 100 shown in FIGS. 10A-10C includes a sidewall 106 which can be vertical or near vertical at its point of intersection with the substrate 101, and curves outward as it rises. In this embodiment, light incident on a lower portion of the sidewall 106 can be more likely to bounce toward another portion of the sidewall while light incident on a higher portion of the sidewall 106 can be more likely to bounce toward the emission surface 108. The package 110 shown in FIGS. 11A-11C includes a sidewall 116 which curves inward as it rises. In this embodiment, light incident on a lower portion of the sidewall 116 can be more likely to bounce toward the emission surface than light incident on the equivalent lower portion of the sidewall 106 of FIGS. 10A-10C.

While the embodiment of FIGS. 9A-9C has a one-part sidewall, packages according to the present invention can also comprise encapsulants having two or more parts. For example, FIGS. 12A-C show an encapsulant 120 with a sidewall 126 having a lower portion 126a and an upper portion 126b. The lower portion 126a is wider than vertical, and thus light incident on this portion can be more likely to bounce angled toward the emission surface 128 than light incident on the upper portion 126b, which can be vertical. The portions 126a, 126b can be switched such that the lower portion is vertical while the upper portion is angled. Further, some encapsulants according to the present invention can have two angled portions, or can comprise three or more portions which can be angled, vertical, or a combination thereof.

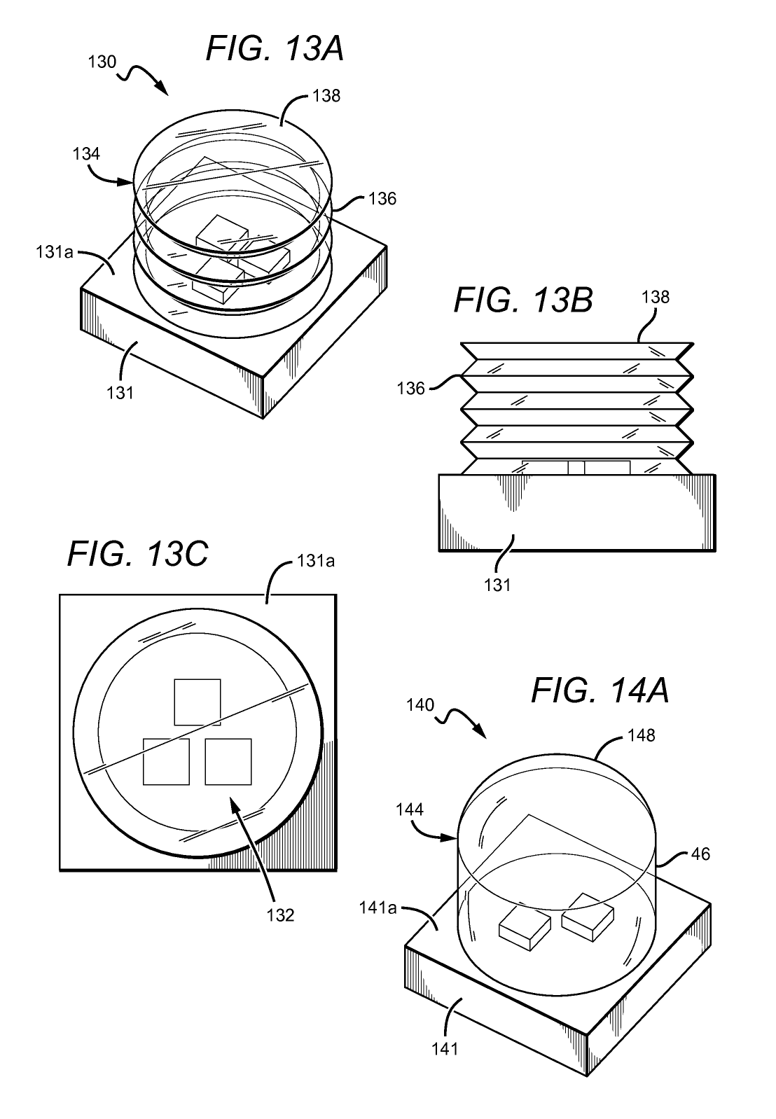

Some embodiments of packages according to the present invention can aid in beam shaping as well as color mixing. One such package 130 is shown in FIGS. 13A-13C. The package 130 comprises an encapsulant 134 includes a jagged reflective sidewall 136. In addition to improving the color uniformity of the emission of the package 130, the jagged reflective sidewall 136 can help in beam shaping to produce a specific light output profile.

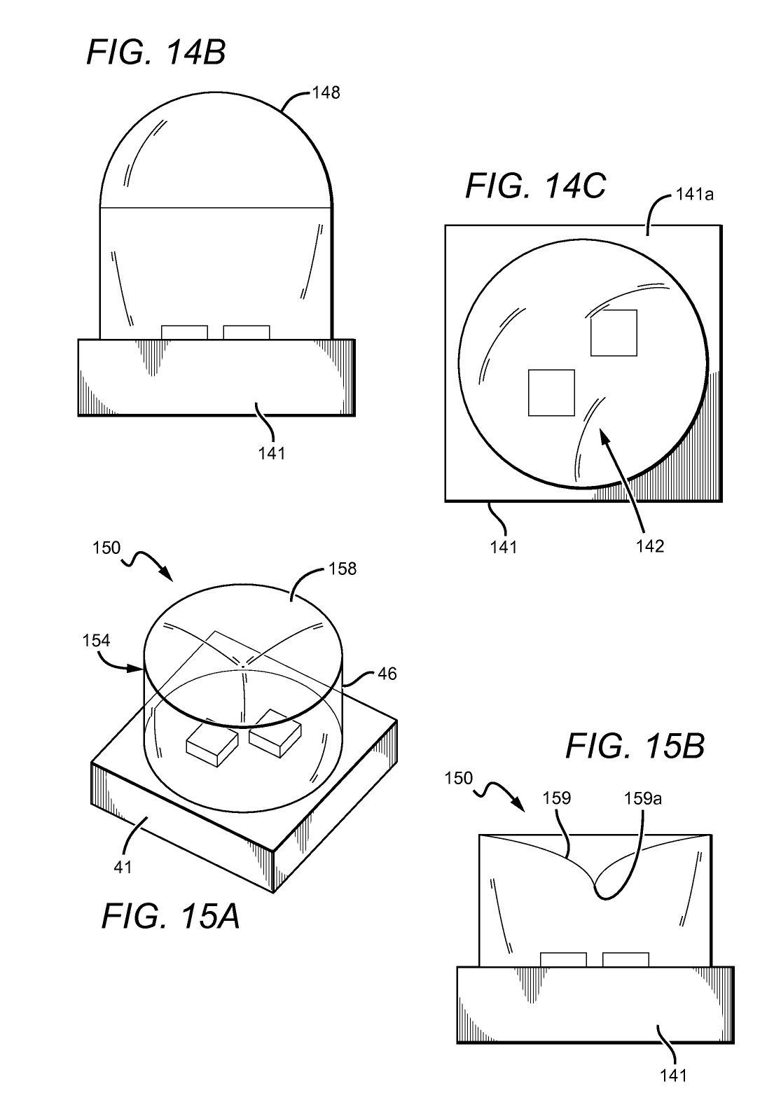

Many other primary optic shapes can also be used to achieve a specific output profile while also aiding in color mixing. Some of these embodiments can comprise encapsulants comprising one or more reflective sidewalls and a shaped top primary emission surface. A first example of such a package 140 is seen in FIGS. 14A-14C. The package 140 comprises an encapsulant 144 similar to the encapsulant of FIGS. 4A-4C and includes a side wall 46, but that includes a frustospherical or hemispheric top surface 148.

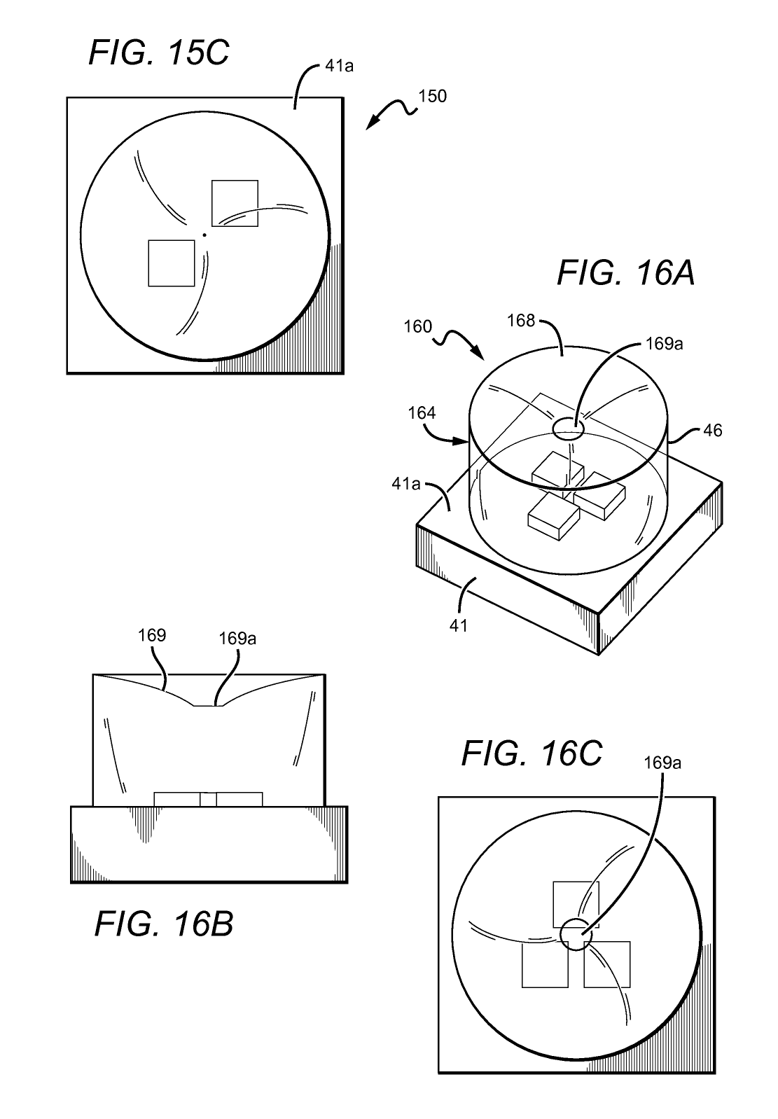

Another example of a package with a shaped top primary emission surface is seen in FIGS. 15A-15C. The package 150 includes an encapsulant 154 with a top surface 158. The top surface 158 includes a concave portion 159 that is generally conical with curved sides and comes to a point 159a. In this embodiment, the primary optic 154 can shape the LED chip emission pattern into a “batwing” type emission pattern. The term “batwing” refers to a light distribution whose luminous intensity is greater along a direction at a significant angle relative to the main axis of distribution rather than along a direction parallel to the main axis. The desirability of a batwing distribution is evident in many lighting applications, including in which most of the light should be distributed in a direction other than along the main axis. In some batwing distributions, multiple peak emissions can be provided that broaden the overall emission pattern.

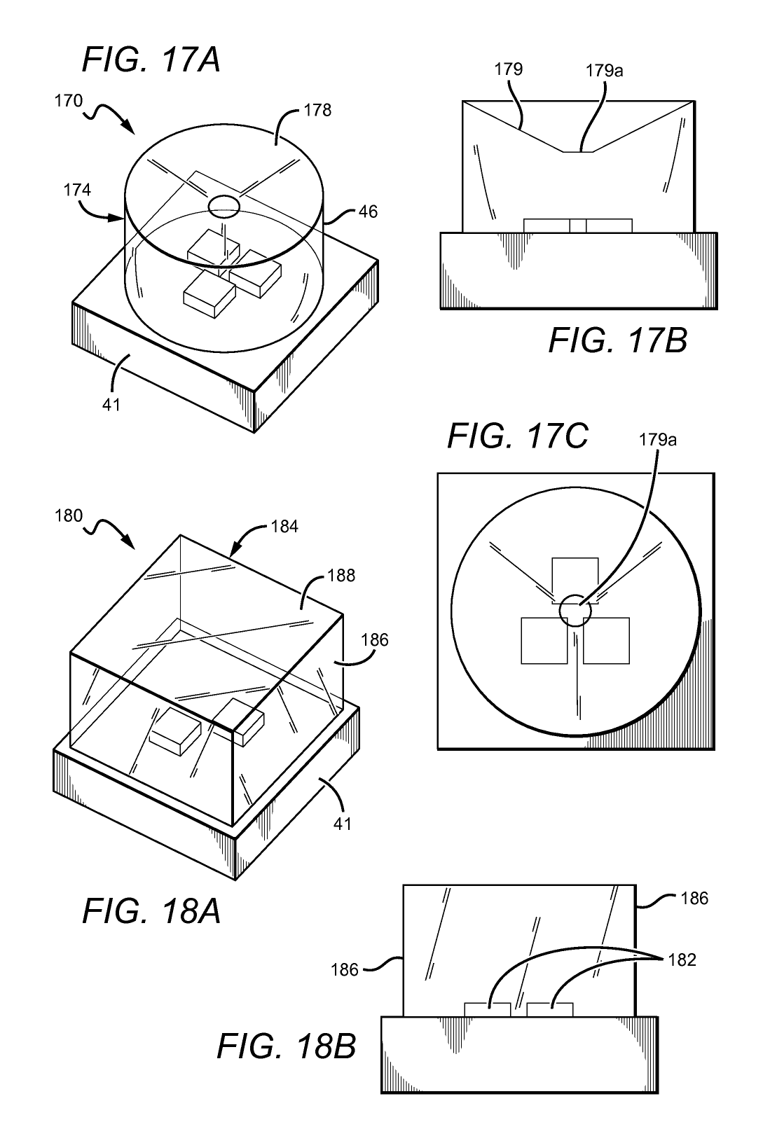

Many variants of the encapsulant 154 from FIGS. 15A-15C are also possible. For example, the encapsulant 164 in FIGS. 16A-16C can include a top surface 168 with a concave portion 169, but instead of coming to a point, the concave portion 169 can include a flat portion 169a that can be, for example, circular, oval, square, rectangular, etc. This shape for the primary optic 164 can also provide a broader emission pattern that in some embodiments can also comprise a batwing type emission pattern. As another example, the encapsulant 174 in FIGS. 17A-17C can include a top surface 178 with a concave portion 179 that can be frustoconical and can have straight sides with a flat portion 179a. In another embodiment, the concave portion can be conical, and thus not have a flat portion. While the FIGS. 14A-17C embodiments include a side wall 46, the emission surfaces of these embodiments can be combined with any of the encapsulants from FIGS. 4A-4C, 6A-13C, and the below 18A-19C.

Embodiments of packages according to the present invention can include many different types of beam shaping primary optics. Some exemplary optics are described in the commonly assigned applications U.S. patent application Ser. No. 13/544,662 to Tarsa et al. and entitled “Primary Optic for Beam Shaping” and U.S. patent application Ser. No. 13/842,307 to Ibbetson et al. and entitled “Low Profile Lighting Module,” both of which are fully incorporated by reference herein in their entirety. More complex shapes and methods of forming these primary optics are described in U.S. patent application Ser. No. 13/306,589 to Tarsa et al. and entitled “Complex Primary Optics and Methods of Fabrication,” which is also commonly assigned and fully incorporated by reference herein in its entirety.

FIGS. 18A-18C shows another embodiment of a package 180 according to the present invention similar in many respects to the package 40 of FIGS. 4A-4C, but the package 180 can have a cube, box, or rectangular prism shaped encapsulant 184. The general cubic shape of the encapsulant 184 can be combined with any of the features above. For example, the cross-section of the encapsulant 184 can be slightly altered such that it is similar to or the same as the vertical cross-sectional view of FIGS. 6B, 7B, or 9B-12B, or the flat top primary emission surface 188 can be altered similarly to the surfaces shown in FIGS. 14A-17C. The package 180 is one embodiment of a package with an encapsulant 184 with planar sides 186 that result in a certain amount of TIR within the encapsulant 184 when the side walls 186 are not 100% reflective, which can increase color mixing. The side walls 186 and the top primary emission surface 188 can be parallel to surfaces of the LED chips 182, which can increase the beneficial TIR from the side walls 186. The advantages of encapsulants with side walls parallel to chip surfaces are described in detail in U.S. application Ser. No. 13/770,389.

FIGS. 19A-19C shows another embodiment of a package 190 according to the present invention. Similar to the package 180 in FIGS. 18A-18C, the package 190 comprises a cubic or rectangular prism shaped encapsulant 194. In the FIGS. 19A-19C embodiment, the sidewalls 196 of the encapsulant 194 can be essentially aligned with or slightly inside of the outer edge of the submount 191. This can help reduce the package footprint. Other encapsulants according to the present invention, including those shown above, can either align with the outer edge of the submount or have a width matching that of the submount (e.g., a cylindrical encapsulant with a diameter equal to the length of one side of a square submount). Similarly, an encapsulant similar to the encapsulant 194 can have side walls which are slightly angled outward, such that the top of the encapsulant is wider than the submount.

Encapsulants according to the present invention can be formed in place over one or more sources as with a mold, or can be fabricated separately and then subsequently attached to by an adhesive epoxy, for example. If an encapsulant includes different sections, such as the encapsulant 120 in FIGS. 12A-12C of the encapsulant 140 in FIGS. 14A-14C, different portions can be attached at different times. For example a second section, in some cases the upper section, can be attached after the first portion has finished curing through fuse molding, or can be attached at the same time through molding. One large mold can be used to form many encapsulants over many sources on a wafer, as with overmolding. The entire encapsulant or portions of the encapsulant may be applied with a pin-needle dispense method. In another embodiment, an ink jet may be used. Other dispense tools are also possible. Some encapsulant portions may be allowed to develop their shape using only gravity while they are cured, while some other portions may develop their shape through both gravity and other processes. Many different curing methods can be used, including but not limited to heat, ultraviolet (UV), and infrared (IR). Methods for attaching an encapsulant to or forming an encapsulant on a surface are discussed in the commonly assigned applications U.S. patent application Ser. No. 13/219,486 to Ibbetson et al. and entitled “White LEDs with Emission Wavelength Correction” and U.S. patent application Ser. No. 13/804,309 to Castillo et al. and entitled “LED Dome with Improved Color Spatial Uniformity,” both of which are fully incorporated by reference herein in their entirety.

Packages according to the present invention can be incorporated into any type of LED lighting fixture, and can eliminate the need for secondary or tertiary optics designed for color mixing. For example, packages according to the present invention can be incorporated into troffers, which could increase the color uniformity and, in indirect lighting troffers, decrease the necessary size (and thus cost) of a mixing chamber. Packages according to the present invention could be incorporated into a direct lighting troffer where prior art packages would necessitate the need for an indirect troffer to achieve adequate color mixing Packages according to the present invention can also be incorporated into bulb-level fixtures, such as MR16 bulbs.

Although the present invention has been described in detail with reference to certain preferred configurations thereof, other versions are possible. The invention can be used in any light fixtures, such as when a uniform light or a near uniform light source is required. In other embodiments, the light intensity distribution of the LED module can be tailored to the particular fixture to produce the desired fixture emission pattern. Therefore, the spirit and scope of the invention should not be limited to the versions described above.

We claim:

1. An emitter package, comprising:
one or more emitters on a submount;
an encapsulant over said emitters and said submount, said encapsulant having at least one reflective surface.

2. The emitter package of claim 1, wherein said encapsulant comprises a mixing chamber.

3. The emitter package of claim 1, further comprising a non-reflective primary emission surface.

4. The emitter package of claim 3, wherein said primary emission surface is a top primary emission surface.

5. The emitter package of claim 4, wherein the emission from said primary emission surface is Lambertian.

6. The emitter package of claim 1, wherein said encapsulant is overmolded.

7. The emitter package of claim 1, wherein said encapsulant has a rectangular vertical cross-section.

8. The emitter package of claim 1, wherein said encapsulant is substantially cylindrical.

9. The emitter package of claim 1, wherein said encapsulant is substantially box shaped.

10. The emitter package of claim 1, wherein said encapsulant comprises at least one side surface and a top surface.

11. The emitter package of claim 10, wherein said top surface is flat.

12. The emitter package of claim 10, wherein said top surface is shaped.

13. The emitter package of claim 10, wherein said top surface is frustospherical.

14. The emitter package of claim 10, wherein said top surface comprises a concave portion.

15. The emitter package of claim 10, wherein said top surface comprises fillets.

16. The emitter package of claim 10, wherein said at least one side surface is vertical.

17. The emitter package of claim 10, wherein said at least one side surface is planar.

18. The emitter package of claim 17, wherein said at least one side surface is parallel to a surface of at least one of said emitters.

19. The emitter package of claim 10, wherein said at least one side surface angles outward.

20. The emitter package of claim 10, wherein said at least one side surface and said submount form at least an 85° angle.

21. The emitter package of claim 11, wherein said at least one side surface curves outward.

22. The emitter package of claim 1, wherein said encapsulant comprises a textured emission surface.

23. The emitter package of claim 1, wherein said encapsulant is substantially rod shaped.

24. The emitter package of claim 1, wherein said at least one reflective surface is a side surface.

25. The emitter package of claim 24, wherein said encapsulant comprises a transparent top surface.

26. The emitter package of claim 24, wherein said at least one reflective surface has variable reflectivity.

27. The emitter package of claim 24, wherein a lower portion of said reflective surface is more reflective than an upper portion of said reflective surface.

28. The emitter package of claim 24, comprising a first reflective side surface and a second reflective side surface;
wherein said first reflective side surface is more reflective than said second reflective side surface.

29. The emitter package of claim 1, wherein said at least one reflective surface comprises reflective white paper.

30. The emitter package of claim 1, wherein said at least one reflective surface comprises a reflective metal.

31. The emitter package of claim 1, wherein said at least one reflective surface comprises a dielectric material.

32. The emitter package of claim 1, wherein said at least one reflective surface comprises a reflective coating.

33. The emitter package of claim 1, wherein said reflective coating is uniformly distributed.

34. The emitter package of claim 1, wherein said reflective coating is non-uniformly distributed.

35. The emitter package of claim 1, comprising at least two emitters.

36. The emitter package of claim 35, wherein said emitters emit different wavelengths of light.

37. The emitter package of claim 1, comprising a red emitter, a green emitter, and a blue emitter.

38. The emitter package of claim 1, comprising a BSY emitter and a red emitter.

39. The emitter package of claim 1, further comprising a scatterer.

40. The emitter package of claim 39, wherein said scatterer comprises scattering particles.

41. The emitter package of claim 40, wherein said scattering particles are uniformly distributed in said encapsulant.

42. The emitter package of claim 40, wherein said scattering particles are non-uniformly distributed in said encapsulant.

43. The emitter package of claim 42, wherein an upper portion of said encapsulant contains less scattering particles than a lower portion of said encapsulant.

44. The emitter package of claim 42, wherein a lower portion of said encapsulatn contains less scattering particles that an upper portion of said encapsulant.

45. The emitter package of claim 39, wherein said scatterer is two-dimensional.

46. The emitter package of claim 39, wherein said scatterer is on a top surface of said encapsulant.

47. The emitter package of claim 39, wherein the height of said encapsulant is smaller than the width of said encapsulant.

48. The emitter package of claim 1, wherein the width of said one or more emitters is at least 50% the width of said encapsulant.

49. The emitter package of claim 1, wherein the width of said one or more emitters is at least 75% the width of said encapsulant.

50. The emitter package of claim 1, wherein said submount comprises a reflective top surface.

51. The emitter package of claim 1, wherein said encapsulant has a width substantially equal to a width of said submount.

52. The emitter package of claim 1, wherein said encapsulant has a width at least as wide as a width of said submount.

53. An emitter package, comprising:
one or more emitters on a submount; and
a mixing chamber over said emitters and on said submount;
wherein said mixing chamber is configured to improve the color spatial uniformity of said package.

54. The emitter package of claim 53, wherein said mixing chamber comprises an encapsulant.

55. The emitter package of claim 53, wherein said mixing chamber comprises a reflective side surface.

56. The emitter package of claim 55, wherein said reflective side surface is vertical.

57. The emitter package of claim 55, wherein said reflective side surface and said submount form at least an 85° angle.

58. The emitter package of claim 55, wherein said at least one reflective surface has variable reflectivity.

59. The emitter package of claim 55, wherein a lower portion of said reflective surface is more reflective than an upper portion of said reflective surface.

60. The emitter package of claim 55, comprising a first reflective side surface and a second reflective side surface;
wherein said first reflective side surface is more reflective than said second reflective side surface.

61. The emitter package of claim 53, wherein said mixing chamber comprises planar side surfaces.

62. The emitter package of claim 53, wherein said mixing chamber comprises a scatterer.

63. The emitter package of claim 53, comprising at least two emitters.

64. The emitter package of claim 63, wherein said emitters emit different wavelengths of light.

65. The emitter package of claim 53, comprising a red emitter, a green emitter, and a blue emitter.

66. The emitter package of claim 53, comprising a BSY emitter and a red emitter.

67. The emitter package of claim 53, wherein said mixing chamber is rod shaped.

68. The emitter package of claim 53, wherein said encapsulant has a width substantially equal to a width of said submount.

69. The emitter package of claim 53, wherein said encapsulant has a width at least as wide as a width of said submount.

70. An emitter encapsulant, comprising:
at least one reflective surface; and
a transparent primary emission surface;
wherein said encapsulant is configured to improve the color spatial uniformity of light emission.

71. The emitter encapsulant of claim 70, wherein said at least one reflective surface is a side surface.

72. The emitter encapsulant of claim 70, wherein said encapsulant has a rectangular vertical cross-section.

73. The emitter encapsulant of claim 70, wherein said encapsulant is substantially cylindrical.

74. The emitter encapsulant of claim 70, wherein said encapsulant is substantially box shaped.

75. The emitter encapsulant of claim 70, further comprising a scatterer.

76. The emitter encapsulant of claim 75, wherein said scatterer is uniformly distributed throughout said encapsulant.

77. The emitter encapsulant of claim 75, wherein said scatterer is two-dimensional.

78. A lighting fixture, comprising:
a housing; and
at least one emitter package on said housing, said emitter package comprising an encapsulant with at least one reflective surface.
